(19) United States
(12) Patent Application Publication
(10) Pub. No.: US 2025/0362258 A1
(43) Pub. Date: Nov. 27, 2025

(54) PRODUCTION LINE NMR MEASUREMENT USING EXTERNAL REFERENCE SAMPLE

(71) Applicant: 4IR Solutions Ltd., Or-Akiva (IL)

(72) Inventors: Tal Cohen, Herzliya (IL); Paul J. Giammatteo, Southbury, CT (US); Mordechai Bercovici, Kiryat Tivon (IL)

(73) Assignee: 4IR Solutions Ltd., Or-Akiva (IL)

(21) Appl. No.: 19/210,500

(22) Filed: May 16, 2025

Related U.S. Application Data
(60) Provisional application No. 63/650,381, filed on May 21, 2024.
(60) Provisional application No. 63/650,387, filed on May 21, 2024.

(51) Int. Cl. G01N 24/08

(52) U.S. Cl. CPC G01N 24/085

(57) ABSTRACT

The present disclosure provides a method for production line nuclear magnetic resonance (NMR) measurement of a fluid containing one or more evaluated materials. The method includes positioning a reference sample with a known reference material and a sample of the fluid within a sensing region of an NMR measurement unit coil and a magnetic field of a permanent magnet. An NMR measurement is performed by feeding at least one radio frequency coil with a signal having a spectrum including characteristic frequencies of the evaluated materials and the reference material, generating detection signals. The detection signals are processed to provide an NMR spectrum with a reference peak and additional peaks. The signal is adjusted based on changes over time of the reference peak frequency, and a band pass frequency range of a receiving unit is adjusted based on the reference peak frequency.

### CROSS-REFERENCE TO RELATED APPLICATIONS

This application claims priority of U.S. Provisional patent No. 63/650,381 filing date May 21, 2024, which is hereby incorporated in its entirety.

This application claims priority of U.S. Provisional patent No. 63/650,387 filing date May 21, 2024, which is hereby incorporated in its entirety.

### FIELD OF INVENTION

The present disclosure relates to nuclear magnetic resonance (NMR) spectroscopy, and more particularly to a method and system for production line NMR measurement of fluids using an external reference sample.

### BACKGROUND

Nuclear magnetic resonance (NMR) spectroscopy is a powerful analytical technique used to study the structure, dynamics, and chemical composition of materials. It relies on the interaction between atomic nuclei and magnetic fields to provide detailed information about molecular structures and chemical environments. NMR spectroscopy has found widespread applications in various fields, including chemistry, biology, medicine, and materials science.

In industrial settings, NMR spectroscopy can be utilized for quality control, process monitoring, and composition analysis of fluids and materials in production lines. However, implementing NMR measurements in such environments presents several challenges. Traditional NMR spectrometers are often large, expensive, and require specialized laboratory conditions, making them unsuitable for integration into production processes.

One of the difficulties in applying NMR spectroscopy to production line measurements is the need for accurate and reliable frequency referencing. In laboratory settings, this is typically achieved by adding a known reference compound, such as tetramethylsilane (TMS), to the sample being analyzed. The reference compound provides a standard peak in the NMR spectrum, allowing for precise determination of chemical shifts and peak positions.

However, introducing reference compounds directly into production line samples is often impractical or undesirable. It may contaminate the product, alter its properties, or interfere with downstream processes. Additionally, in continuous flow systems, it can be challenging to maintain a consistent concentration of the reference compound throughout the measurement process.

Another challenge in production line NMR measurements is the potential for variations in the magnetic field strength over time. Fluctuations in temperature, mechanical vibrations, or other environmental factors can cause slight changes in the magnetic field, leading to shifts in the observed NMR frequencies. Without a reliable reference point, these shifts can complicate the interpretation of NMR spectra and reduce the accuracy of quantitative measurements.

Furthermore, the design of NMR probes for production line applications requires careful consideration of factors such as sample flow, temperature control, and compatibility with the production environment. The probe must be capable of providing consistent and reproducible measurements while withstanding the conditions present in industrial settings.

As industries seek to implement more advanced analytical techniques for real-time monitoring and quality control, there is a growing interest in developing NMR systems that can overcome these challenges and provide accurate, reliable measurements in production line environments. Such systems could potentially offer valuable insights into process parameters, product composition, and quality attributes without disrupting the production flow or compromising product integrity.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an embodiment, a method for production line nuclear magnetic resonance (NMR) measurement of a fluid containing one or more evaluated materials is provided. The method includes positioning a reference sample including a known reference material and a sample of the fluid within a sensing region of an NMR measurement unit coil of a production line NMR measurement device, and within a magnetic field of a permanent magnet of the production line NMR measurement device. The method further includes performing an NMR measurement by feeding at least one radio frequency coil of the production line NMR measurement device with a signal having a spectrum that includes one or more characteristic frequencies of one or more nucleus of the one or more evaluated materials and a characteristic frequency of the known reference material, generating detection signals indicative of sensed radio frequency emissions associated with the reference sample and the one or more evaluated materials. The method also includes processing the detection signals to provide an NMR spectrum comprising a reference peak associated with the reference material and one or more additional peaks associated with the one or more evaluated materials. Additionally, the method includes identifying the one or more evaluated materials based on one or more frequency differences between the reference peak and each one of the additional peaks.

According to other aspects of the present disclosure, the method may include one or more of the following features. The method may further comprise determining concentrations of the one or more evaluated materials within the fluid based on attributes of the reference peak and the one or more additional peaks. The reference sample may be positioned within a reference sample housing located adjacent to a fluid conduit containing the sample of the fluid. The at least one radio frequency coil may comprise a first RF coil wound around both the fluid conduit and the reference sample housing. Alternatively, the at least one radio frequency coil may comprise a first RF coil wound around the fluid conduit and a second RF coil wound around the reference sample housing. The method may further comprise adjusting the signal based on changes over time of a frequency of the reference peak. The method may also include adjusting a band pass frequency range of a receiving unit based on the frequency of the reference peak.

According to another aspect of the present disclosure, a production line nuclear magnetic resonance (NMR) measurement device is provided. The device includes a permanent magnet configured to generate a magnetic field, an NMR measurement unit coil defining a sensing region, a fluid conduit for containing a fluid sample with one or more evaluated materials, a reference sample housing positioned outside the fluid conduit and containing a known reference material, at least one radio frequency coil configured to generate radio frequency emissions and detect radio frequency emissions, and a processor. The processor is configured to control the at least one radio frequency coil to perform an NMR measurement on the fluid sample and the reference sample, process detection signals to provide an NMR spectrum comprising a reference peak associated with the reference material and one or more additional peaks associated with the one or more evaluated materials, and identify the one or more evaluated materials based on one or more frequency differences between the reference peak and each one of the additional peaks.

According to other aspects of the present disclosure, the production line NMR measurement device may include one or more of the following features. The processor may be further configured to determine concentrations of the one or more evaluated materials within the fluid based on attributes of the reference peak and the one or more additional peaks. The at least one radio frequency coil may comprise a first RF coil wound around both the fluid conduit and the reference sample housing. Alternatively, the at least one radio frequency coil may comprise a first RF coil wound around the fluid conduit and a second RF coil wound around the reference sample housing. The processor may be further configured to adjust a signal fed to the at least one radio frequency coil based on changes over time of a frequency of the reference peak. The processor may also be configured to adjust a band pass frequency range of a receiving unit based on the frequency of the reference peak. The reference sample housing may be configured to store two or more reference materials.

According to another aspect of the present disclosure, a system for production line nuclear magnetic resonance (NMR) measurement is provided. The system includes a fluid conduit for containing a fluid sample with one or more evaluated materials, a reference sample housing positioned outside the fluid conduit and containing a known reference material, an NMR measurement device including a permanent magnet and at least one radio frequency coil, the NMR measurement device configured to perform an NMR measurement on the fluid sample and the reference sample, and a processor. The processor is configured to process detection signals from the NMR measurement to provide an NMR spectrum comprising a reference peak associated with the reference material and one or more additional peaks associated with the one or more evaluated materials, and identify the one or more evaluated materials based on one or more frequency differences between the reference peak and each one of the additional peaks.

According to an embodiment, the processor may be further configured to determine concentrations of the one or more evaluated materials within the fluid sample based on attributes of the reference peak and the one or more additional peaks.

According to an embodiment, the at least one radio frequency coil may comprise a first RF coil wound around both the fluid conduit and the reference sample housing. Alternatively, the at least one radio frequency coil may comprise a first RF coil wound around the fluid conduit and a second RF coil wound around the reference sample housing.

According to an embodiment, the processor may be further configured to adjust a signal fed to the at least one radio frequency coil based on changes over time of a frequency of the reference peak. The processor may also be configured to adjust a band pass frequency range of a receiving unit based on the frequency of the reference peak.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates a flowchart of a method for production line nuclear magnetic resonance (NMR) measurement, showing the key steps involved in the process.

FIG. 2 depicts examples of NMR spectra obtained using the production line NMR measurement device, showing a reference peak and at least one additional peaks that drift due to changes in the magnetic field of the magnet and/or measurement conditions.

FIG. 3 shows a graph of RF matching characteristics at 200.13 MHz for the NMR measurement system, displaying the frequency response curve with a resonance dip.

FIG. 4 presents a block diagram of an NMR measurement system, illustrating the arrangement of key components including the probe, magnets, RF coils, and fluid conduit.

FIG. 5 shows two section views of different RF coil configurations in the NMR measurement arrangement, comparing a single-coil design and a dual-coil design.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

An example of a production line NMR measurement system is the Process NMR AI-60 of 4IRsolutions Ltd., of Israel.

The present disclosure relates to a production line nuclear magnetic resonance (NMR) measurement system for analyzing fluids in industrial settings. This system may provide real-time, non-invasive analysis of fluid compositions and properties as they flow through production lines or process streams.

In some cases, the production line NMR measurement system may include a permanent magnet configured to generate a strong, uniform magnetic field within a measurement region. The system may also comprise one or more radio frequency (RF) coils designed to both emit RF pulses and detect RF signals from the sample being measured.

The system may incorporate an NMR measurement unit coil that defines a sensing region where the fluid sample interacts with the applied magnetic fields and RF fields. This sensing region may be optimized to provide high sensitivity and resolution for the specific fluids and materials being analyzed.

A processor may be included to control the RF coils and coordinate the timing of RF pulses and signal acquisition. The processor may also process the detected NMR signals to extract relevant information about the fluid composition and properties.

In some implementations, the system may include a fluid conduit that allows the sample fluid to flow through the measurement region. This conduit may be designed to minimize disruption to the production process while still enabling accurate NMR measurements.

A feature of the system may be a reference sample housing positioned outside the fluid conduit. This housing may contain a known reference material that provides a fixed reference point for calibrating and interpreting the NMR spectra. By keeping the reference sample separate from the fluid stream, the system may avoid contamination issues while still maintaining measurement accuracy.

Furthermore—having the reference sample guarantees that the reception unit always receives at least one signal (for example a reference peak associated with the reference sample)—which allows the production line NMR measurement system to operate in a seamless and automatic manner—even when the signals associated with the fluid do not exist or are hard to detect.

The reference peak may be used to adjust the signal sent to the RF coli and to adjust the bandwidth of a bans pass of the reception unit.

The combination of these components may enable the production line NMR measurement system to perform rapid, non-destructive analysis of fluids without interrupting the production process. This capability may be valuable in various industries for quality control, process optimization, and real-time monitoring of fluid properties and compositions.

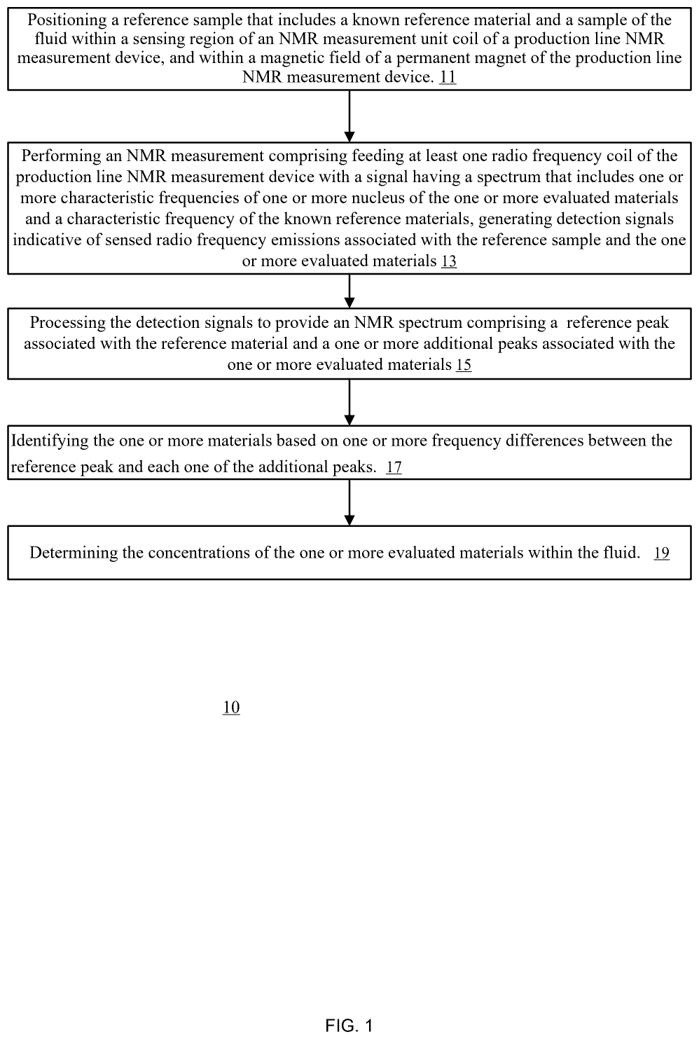

The present disclosure relates to a method for production line NMR measurement of a fluid containing one or more evaluated materials. FIG. 1 illustrates a flowchart of a method 10 for production line NMR measurement.

In some cases, a method 10 may begin with a step 11 of positioning a reference sample and a sample of the fluid within a sensing region of an NMR measurement unit coil of a production line NMR measurement device. The reference sample may include a known reference material. Both the reference sample and the fluid sample may be positioned within a magnetic field of a permanent magnet of the production line NMR measurement device.

A step 13 of the method 10 may involve performing an NMR measurement. This step may comprise feeding at least one radio frequency coil of the production line NMR measurement device with a signal. The signal may have a spectrum that includes one or more characteristic frequencies of one or more nucleus of the one or more evaluated materials and a characteristic frequency of the known reference material. The NMR measurement may generate detection signals indicative of sensed radio frequency emissions associated with the reference sample and the one or more evaluated materials.

In some cases, a step 15 of the method 10 may include processing the detection signals. This processing may provide an NMR spectrum comprising a reference peak associated with the reference material and one or more additional peaks associated with the one or more evaluated materials.

A step 17 of the method 10 may involve adjusting the signal based on changes over time of a frequency of the reference peak; and adjusting a band pass frequency range of a receiving unit based on the frequency of the reference peak. This may guarantee that the receiving unit will receive at least one peak.

According to an embodiment the method may also include at least one of (a) identifying the one or more evaluated materials. This identification may be based on one or more frequency differences between the reference peak and each one of the additional peaks in the NMR spectrum, (b) determining concentrations of the one or more evaluated materials within the fluid. This determination may be based on attributes of the reference peak and the one or more additional peaks in the NMR spectrum.

The method 10 may allow for accurate NMR measurements in a production line setting without the need to introduce reference materials directly into the fluid being analyzed. By using a separate reference sample, the method 10 may provide a stable reference point for identifying and quantifying the evaluated materials in the fluid sample.

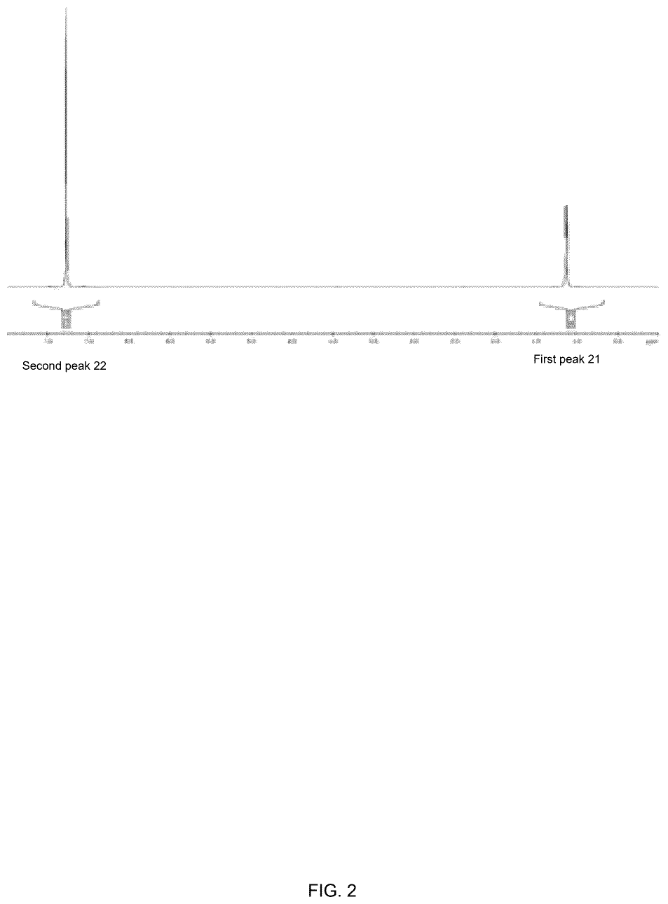

In some cases, the method 10 may involve analyzing an NMR spectrum to identify and quantify materials in a fluid sample. FIG. 2 illustrates an example NMR spectrum that may be obtained using the production line NMR measurement device.

The NMR spectrum in FIG. 2 includes a reference peak 21 and additional peaks 22-25 associated with one or more evaluated materials.

As illustrated in FIG. 2—the spectrum may drift over time due to changes in the environment (for example temperature) and/or sue to other parameters that impact the measurements.

Despite the drift the frequency gap between the reference peak and each additional peak maintains the same.

According to an embodiment the evaluated materials are known and the reference material is selected so that the reference peak is located to the side of any of the additional peaks associated with any of the evaluated signals).

The processor 50 may be configured to process detection signals to provide the NMR spectrum comprising the reference peak 21 associated with the reference material and at least one of the additional peaks 22-25 associated with one or more evaluated materials. In some cases, the NMR spectrum may include additional peaks corresponding to other evaluated materials in the fluid sample.

The processor 50 may be configured to identify the one or more evaluated materials based on one or more frequency differences between the first peak 21 and at least one of the additional peaks 22-25. The frequency difference between these peaks may be characteristic of the specific evaluated material, allowing for its identification. In some cases, the processor 50 may compare the observed frequency differences to a database of known materials to determine the identity of the evaluated material.

Furthermore, the processor 50 may be configured to determine concentrations of the one or more evaluated materials within the fluid based on attributes of the first peak 21 and the one or more additional peaks 22-25. These attributes may include peak height, peak area, or other measurable characteristics of the NMR peaks. In some cases, the relative intensities of the first peak 21 and the one or more additional peaks 22-25 may be used to calculate the concentration of the evaluated material in the fluid sample.

The use of the first peak 21 as a reference may allow for accurate identification and quantification of the evaluated materials even in the presence of variations in the magnetic field or other experimental conditions. This approach may enable reliable analysis of fluid compositions in a production line setting without the need to introduce reference materials directly into the fluid stream.

In some cases, the production line NMR measurement device may include RF matching characteristics that are crucial for optimizing the performance of the NMR measurement system.

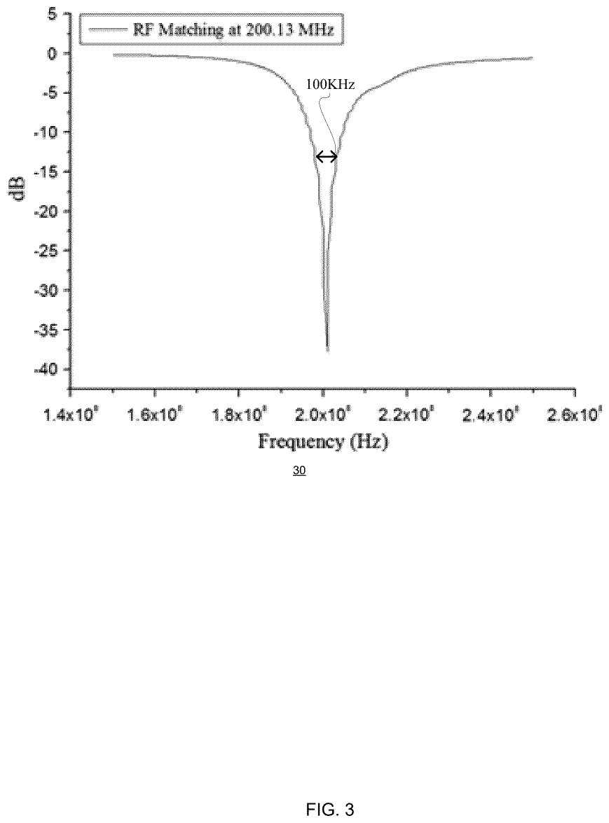

FIG. 3 illustrates a graph showing RF matching characteristics at 200.13 MHz for the NMR measurement system. The graph displays a frequency response curve plotted with frequency (Hz) on the x-axis ranging from 1.4×10⁷ to 2.6'10⁷ Hz and signal strength (dB) on the y-axis ranging from −40 to 5 dB. A page number 30 may be visible in the upper right corner of the figure.

The response curve in FIG. 3 shows a sharp resonance dip centered around 2.0×10⁷ Hz, reaching approximately −37 dB at its lowest point. A bandwidth marker indicates a 100 KHz span across the resonance feature where the response is below −10 dB. The curve exhibits a symmetric shape with steep slopes on both sides of the central resonance frequency.

In some cases, the RF band pass frequency response may be engineered and adjusted to ensure that the RF coil can respond effectively to the frequencies of both the reference sample and the fluid sample. The bandwidth of the RF coil, as indicated by the 100 KHz span in FIG. 3, may be designed to be wide enough to encompass the slight frequency difference between the first peak 21 and the second peak 22. This frequency difference may arise due to the variation in the magnetic field experienced by the reference sample and the fluid sample within the NMR measurement device.

The band pass filter frequency response may be adjustable and may be tailored to one or more oscillation frequencies associated with one or more materials within the reference sample and in the fluid that are being measured. In some cases, the band pass filter frequency response may be scanned over one or more frequency regions of interest to provide one or more spectra. This scanning capability may allow the NMR measurement system to detect and analyze multiple materials with different resonance frequencies.

The steep slopes of the response curve on either side of the central resonance frequency may help to ensure good sensitivity and selectivity in detecting the NMR signals from both the reference sample and the fluid sample. The depth of the resonance dip (approximately −37 dB) may indicate strong coupling between the RF coil and the nuclear spins in the samples, which may contribute to improved signal-to-noise ratio in the NMR measurements.

The symmetric shape of the response curve may be beneficial for maintaining consistent sensitivity across the frequency range where the first peak 21 and the one or more additional peaks 22-25 are expected to appear. This consistency may contribute to the accuracy of the concentration determination performed by the processor 50, which may rely on comparing attributes of the first peak 21 and the one or more additional peaks 22-25.

In some cases, the ability to adjust and tailor the band pass filter frequency response may allow the NMR measurement system to adapt to different measurement scenarios and materials. This flexibility may enable the system to optimize its performance for various fluid compositions and reference materials, enhancing its versatility in production line applications.

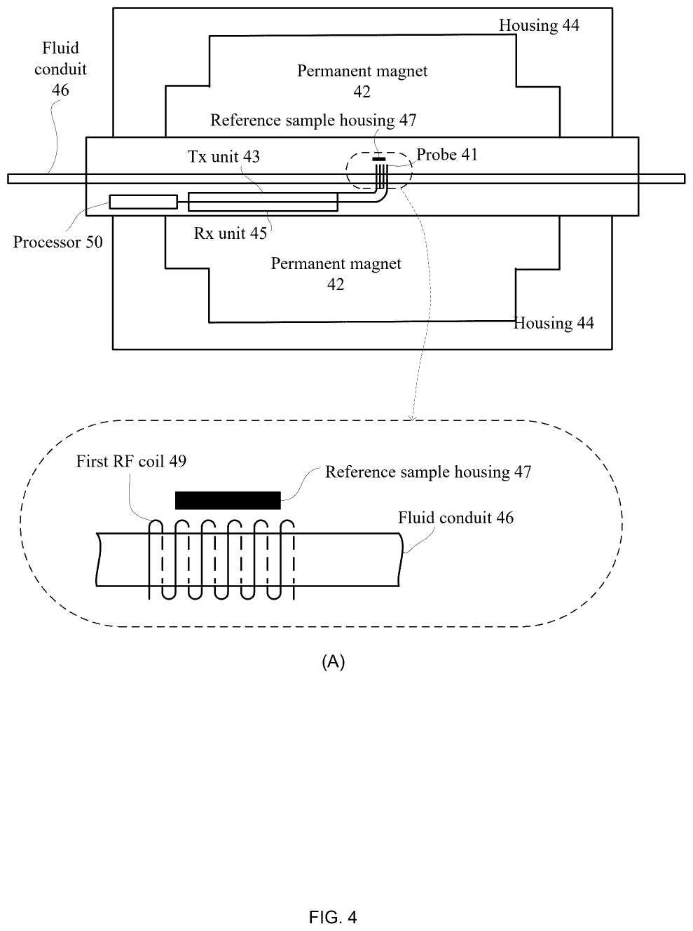

In some cases, the production line NMR measurement system may include various components arranged to perform NMR measurements on fluid samples. FIG. 4 illustrates a block diagram of an NMR measurement system.

The NMR measurement system may include a probe 41 positioned within a magnetic housing 44. The magnetic housing 44 may contain permanent magnets 42 arranged to generate a magnetic field across the measurement region. The magnetic housing 44 may provide structural support and magnetic field containment for the permanent magnets 42.

In some cases, the probe 41 may contain a transmitter unit 43 and a receiver unit 45 arranged along a fluid conduit 46. The fluid conduit 46 may allow the sample fluid to flow through the measurement region. A reference sample housing 47 may be positioned adjacent to the fluid conduit 46. The reference sample housing 47 may maintain a fixed reference material adjacent to the fluid path.

The system may include an RF coil 49 that may be wound around both the fluid conduit 46 and reference sample housing 47. This configuration may allow simultaneous RF excitation and detection from both the sample and reference materials. In some cases, the reference sample housing 47 may be positioned parallel to the fluid conduit 46 within the RF coil 49 winding.

The processor 50 may be connected to the system components to control the NMR measurement operations and process the measurement signals. The processor 50 may coordinate the timing of RF pulses generated by the transmitter unit 43 and signal acquisition by the receiver unit 45.

In some cases, the reference sample may be contained in a sealed capillary outside the RF coil 49 within the probe 41. This arrangement may allow the reference sample to experience a slightly different magnetic field compared to the center of the probe 41, which may house the fluid sample.

The reference sample housing 47 may be configured to store two or more reference materials in some cases. This configuration may allow for multiple reference points or the ability to analyze different types of materials within the same measurement system.

By positioning the reference sample within the reference sample housing 47 adjacent to the fluid conduit 46, the NMR measurement system may provide a stable reference point for identifying and quantifying the evaluated materials in the fluid sample without introducing reference materials directly into the fluid being analyzed.

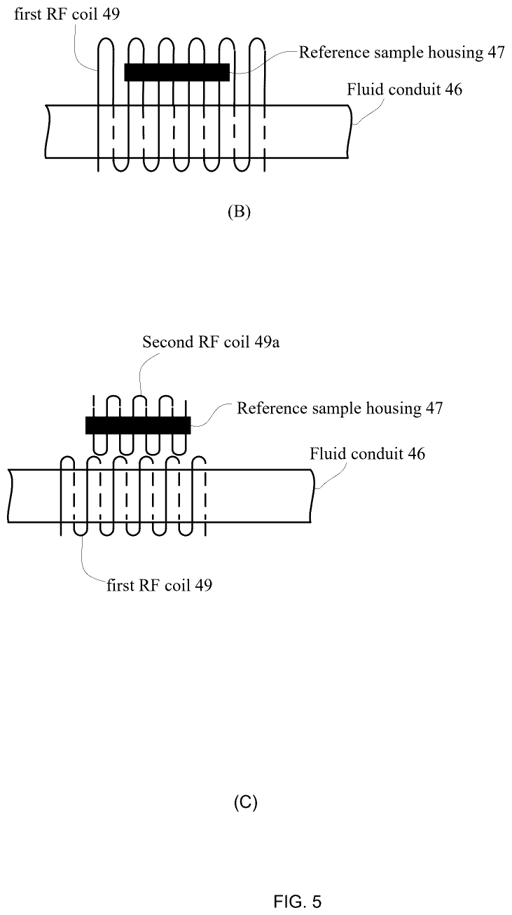

In some cases, the production line NMR measurement system may employ different configurations of radio frequency (RF) coils to optimize performance for specific measurement scenarios. FIG. 5 illustrates two section views labeled (B) and (C) of an NMR measurement arrangement, showcasing different configurations of RF coils around a fluid conduit 46 and a reference sample housing 47.

View (B) in FIG. 5 depicts a single-coil design where the RF coil 49 is wound around both the fluid conduit 46 and the reference sample housing 47. In this configuration, the RF coil 49 may simultaneously excite and detect NMR signals from both the fluid sample and the reference sample. The reference sample housing 47 may appear as a solid rectangular section positioned within the coil windings, while the fluid conduit 46 may extend horizontally through the arrangement.

In contrast, view (C) in FIG. 5 illustrates a dual-coil arrangement. In this configuration, a first RF coil 49 may be wound around the fluid conduit 46, while a second RF coil 49a may be separately wound around the reference sample housing 47. The fluid conduit 46 may continue to extend horizontally through the arrangement, with the reference sample housing 47 maintaining its solid rectangular appearance.

The single-coil design shown in view (B) may offer advantages in terms of simplicity and compactness. By using a single RF coil 49 to interact with both the fluid sample and the reference sample, this configuration may reduce the overall complexity of the NMR measurement system. In some cases, the single-coil design may provide more uniform RF field distribution across both samples, potentially leading to more consistent measurements.

The dual-coil arrangement depicted in view (C) may offer greater flexibility and control over the NMR measurements. By using separate RF coils for the fluid sample and the reference sample, this configuration may allow for independent optimization of RF parameters for each sample. In some cases, the dual-coil arrangement may enable more precise tuning of the RF fields to account for differences in the magnetic environment experienced by the fluid sample and the reference sample.

The choice between the single-coil and dual-coil configurations may depend on various factors such as the specific materials being analyzed, the required measurement precision, and the overall system design constraints. In some cases, the single-coil design may be preferred for applications where simplicity and space efficiency are paramount. The dual-coil arrangement may be advantageous in scenarios where independent control of RF excitation and detection for the fluid and reference samples is desired.

Both configurations may enable the production line NMR measurement system to perform accurate measurements without introducing reference materials directly into the fluid stream. By keeping the reference sample separate from the fluid sample, these arrangements may help maintain the integrity of the production process while still providing a stable reference point for NMR measurements.

In some cases, the production line NMR measurement system may operate by generating, detecting, and processing NMR signals from both the fluid sample and the reference sample. The system may use a radio frequency (RF) signal to excite the nuclei in both samples, and then detect the resulting RF emissions.

The system may include a processor configured to control the generation of RF signals and the detection of NMR signals. In some cases, the processor may adjust the RF signal fed to the radio frequency coil based on changes over time in the frequency of the reference peak. This adjustment may help compensate for drift in the magnetic field or other environmental factors that could affect the NMR measurements.

The reference sample may serve as a calibration standard for the system. By comparing the known properties of the reference material to the observed NMR signals, the system may calibrate its measurements of the fluid sample. In some cases, the reference sample may be used as a ‘lock’ mechanism in continuous experiments. This may involve monitoring the changes in the resonance frequency of the material in the reference sample and adjusting the system parameters accordingly.

The processor may be configured to adjust the band pass frequency range of a receiving unit based on the frequency of the reference peak. This adjustment may ensure that the system remains sensitive to the relevant NMR signals even if there are slight shifts in the resonance frequencies over time.

In some cases, the system may use the reference peak to identify and quantify the materials in the fluid sample. By measuring the frequency differences between the reference peak and the peaks associated with the fluid sample, the system may determine the identity and concentration of various materials in the fluid.

The processor may continuously monitor the frequency of the reference peak during operation. If changes are detected, the processor may adjust various system parameters to maintain measurement accuracy. These adjustments may include modifying the RF signal frequency, adjusting the timing of pulse sequences, or updating the frequency ranges used for signal detection and processing.

By using the reference sample to calibrate and adjust the system in real-time, the production line NMR measurement system may maintain accurate measurements even in dynamic industrial environments where conditions may change over time.

In some cases, the production line NMR measurement system may find applications across various industrial settings where real-time, non-invasive analysis of fluid compositions and properties is beneficial. The system may be utilized in chemical processing plants to monitor reaction progress and product quality. In petroleum refineries, the system may analyze crude oil compositions and monitor the efficiency of refining processes. The food and beverage industry may employ the system for quality control of liquid products and process optimization.

The use of an external reference sample in the production line NMR measurement system may provide several advantages over traditional NMR measurement approaches. By positioning the reference sample outside the fluid conduit, the system may avoid contamination of the production stream with reference materials. This configuration may allow for continuous measurements without interrupting the production process or altering the composition of the fluid being analyzed.

In some cases, the external reference sample may serve as a stable calibration point for the NMR measurements. The known properties of the reference material may allow for accurate identification and quantification of materials in the fluid sample, even in the presence of variations in the magnetic field or other experimental conditions. This approach may enhance the reliability and reproducibility of measurements in dynamic industrial environments.

The system's ability to perform measurements without adding reference materials to the fluid stream may be particularly advantageous in scenarios where product purity is paramount, such as in pharmaceutical manufacturing or food production. The non-invasive nature of the measurements may also be beneficial in processes where introducing additional substances may alter the properties of the fluid or interfere with downstream operations.

In some cases, the production line NMR measurement system may overcome challenges associated with online process monitoring. The use of a permanent magnet and optimized RF coil configurations may allow for compact and robust system designs suitable for integration into existing production lines. The system's ability to provide real-time data on fluid compositions and properties may enable rapid process adjustments and quality control decisions, potentially improving overall production efficiency and product consistency.

The external reference sample approach may also address challenges related to magnetic field inhomogeneities in industrial settings. By providing a consistent reference point, the system may compensate for variations in the magnetic field that may occur due to nearby equipment or environmental factors. This capability may enhance the accuracy and reliability of measurements in less-than-ideal conditions often encountered in production environments.

In some cases, the flexibility of the production line NMR measurement system may allow for analysis of a wide range of materials and fluid compositions. The ability to adjust RF parameters and use multiple reference materials may enable the system to adapt to different measurement scenarios and materials, enhancing its versatility across various industrial applications.

The non-destructive nature of NMR measurements may be advantageous in situations where preserving the integrity of the sample is important. This characteristic may allow for continuous monitoring of valuable or sensitive materials without waste or loss of product.

In some cases, the production line NMR measurement system may facilitate improved process control and quality assurance. The ability to perform rapid, in-line measurements may enable real-time adjustments to process parameters, potentially reducing waste, optimizing resource utilization, and ensuring consistent product quality.

The system's capacity for continuous monitoring may also contribute to enhanced safety in industrial processes. By providing real-time data on fluid compositions, the system may help detect anomalies or deviations from expected parameters, allowing for prompt corrective actions and potentially preventing hazardous situations.

In some cases, the production line NMR measurement system may support efforts towards process automation and Industry 4.0 initiatives. The system's ability to provide continuous, reliable data on fluid properties and compositions may integrate well with digital control systems and data analytics platforms, potentially enabling more sophisticated process optimization and predictive maintenance strategies.

A number of implementations have been described. Nevertheless, it will be understood that various modifications may be made without departing from the spirit and scope of the disclosure. Accordingly, other implementations are within the scope of the following claims.

1. A method for production line nuclear magnetic resonance (NMR) measurement of a fluid containing one or more evaluated materials, comprising:
positioning a reference sample including a known reference material and a sample of the fluid within a sensing region of an NMR measurement unit coil of a production line NMR measurement device, and within a magnetic field of a permanent magnet of the production line NMR measurement device;
performing an NMR measurement by feeding at least one radio frequency coil of the production line NMR measurement device with a signal having a spectrum that includes one or more characteristic frequencies of one or more nucleus of the one or more evaluated materials and a characteristic frequency of the known reference material, generating detection signals indicative of sensed radio frequency emissions associated with the reference sample and the one or more evaluated materials;
processing the detection signals to provide an NMR spectrum comprising a reference peak associated with the reference material and one or more additional peaks associated with the one or more evaluated materials;
adjusting the signal based on changes over time of a frequency of the reference peak; and
adjusting a band pass frequency range of a receiving unit based on the frequency of the reference peak.

2. The method of claim 1, further comprising identifying the one or more evaluated materials based on one or more frequency differences between the reference peak and each one of the additional peaks.

3. The method of claim 1, further comprising determining concentrations of the one or more evaluated materials within the fluid based on attributes of the reference peak and the one or more additional peaks.

4. The method of claim 1, wherein the reference sample is positioned within a reference sample housing located adjacent to a fluid conduit containing the sample of the fluid.

5. The method of claim 4, wherein the at least one radio frequency coil comprises a first RF coil wound around both the fluid conduit and the reference sample housing.

6. The method of claim 4, wherein the at least one radio frequency coil comprises: a first RF coil wound around the fluid conduit; and a second RF coil wound around the reference sample housing.

7. A production line nuclear magnetic resonance (NMR) measurement system, comprising:
a permanent magnet configured to generate a magnetic field;
an NMR measurement unit coil defining a sensing region;
a fluid conduit for containing a fluid sample with one or more evaluated materials;
a reference sample housing positioned outside the fluid conduit and containing a known reference material;
at least one radio frequency coil configured to generate radio frequency emissions and detect radio frequency emissions; and
a processor configured to:
control the at least one radio frequency coil to perform an NMR measurement on the fluid sample and the reference sample by feeding the at least one radio frequency coil with a signal having a spectrum that includes one or more characteristic frequencies of one or more nucleus of the one or more evaluated materials and a characteristic frequency of the known reference material;
process detection signals to provide an NMR spectrum comprising a reference peak associated with the reference material and one or more additional peaks associated with the one or more evaluated materials;
adjust the signal based on changes over time of a frequency of the reference peak; and
adjust a band pass frequency range of a receiving unit based on the frequency of the reference peak.

8. The system of claim 7, wherein the processor is further configured to identify the one or more evaluated materials based on one or more frequency differences between the reference peak and each one of the additional peaks.

9. The system of claim 7, wherein the processor is further configured to determine concentrations of the one or more evaluated materials within the fluid based on attributes of the reference peak and the one or more additional peaks.

10. The system of claim 7, wherein the at least one radio frequency coil comprises a first RF coil wound around both the fluid conduit and the reference sample housing.

11. The system of claim 7, wherein the at least one radio frequency coil comprises:
a first RF coil wound around the fluid conduit; and
a second RF coil wound around the reference sample housing.

12. A non-transitory computer-readable medium storing instructions that, when executed by a processor of a production line nuclear magnetic resonance (NMR) measurement system, cause the processor to perform operations comprising:
controlling at least one radio frequency coil to perform an NMR measurement on a fluid sample containing one or more evaluated materials and a reference sample containing a known reference material, wherein the fluid sample and the reference sample are positioned within a sensing region of an NMR measurement unit coil and within a magnetic field of a permanent magnet;
feeding the at least one radio frequency coil with a signal having a spectrum that includes one or more characteristic frequencies of one or more nucleus of the one or more evaluated materials and a characteristic frequency of the known reference material;
processing detection signals to provide an NMR spectrum comprising a reference peak associated with the reference material and one or more additional peaks associated with the one or more evaluated materials;
adjusting the signal based on changes over time of a frequency of the reference peak; and
adjusting a band pass frequency range of a receiving unit based on the frequency of the reference peak.

13. The non-transitory computer-readable medium of claim 12, wherein the operations further comprise identifying the one or more evaluated materials based on one or more frequency differences between the reference peak and each one of the additional peaks.

14. The non-transitory computer-readable medium of claim 12, wherein the operations further comprise determining concentrations of the one or more evaluated materials within the fluid based on attributes of the reference peak and the one or more additional peaks.
